(19) United States
(12) Patent Application Publication
(10) Pub. No.: US 2012/0267646 A1
(43) Pub. Date: Oct. 25, 2012

(54) ORGANIC LIGHT EMITTING DIODE DISPLAY AND METHOD FOR MANUFACTURING THE SAME

(75) Inventor: Tae-Gon KIM, Yongin-City (KR)

(73) Assignee: SAMSUNG MOBILE DISPLAY CO., LTD., Yongin-City (KR)

(21) Appl. No.: 13/323,682

(22) Filed: Dec. 12, 2011

(30) Foreign Application Priority Data
Apr. 22, 2011 (KR) 10-2011-0037944

(51) Int. Cl. H01L 27/15; H01L 33/58

(52) U.S. Cl. 257/88; 438/27; 257/40; 257/E27.121; 257/E33.059

(57) ABSTRACT

An organic light emitting diode display includes a substrate; an organic light emitting element provided over the substrate; a thin film encapsulation layer configured to seal the organic light emitting element together with the substrate; a phase delay layer provided over the thin film encapsulation layer and contacting the thin film encapsulation layer; and a polarizing film attached to the phase delay layer and having an area smaller than that of the phase delay layer.

### RELATED APPLICATIONS

This application claims priority to and the benefit of Korean Patent Application No. 10-2011-0037944 filed in the Korean Intellectual Property Office on Apr. 22, 2011, the entire contents of which are incorporated herein by reference.

### BACKGROUND

1. Field

The present disclosure relates generally to an organic light emitting diode (OLED) display and a method for manufacturing an organic light emitting diode (OLED) display. More particularly, the present disclosure relates generally to an organic light emitting diode (OLED) display using a thin film encapsulation layer as an encapsulation member and a method for manufacturing an organic light emitting diode (OLED) display.

2. Description of the Related Art

Organic light emitting diode display that display images have been in the spotlight.

The organic light emitting diode displays have self-emitting characteristics and do not need a separate light source such that the thickness and weight thereof are decreased, and are distinguished from a liquid crystal display in this aspect. In addition, the organic light emitting diode displays have high-grade characteristics such as low power consumption, high luminance, high reaction speed, and the like.

In general, an OLED display includes a substrate, an organic light emitting diode disposed on the substrate and displaying an image, and an encapsulation member facing the substrate while interposing the organic light emitting diode therebetween to encapsulate the organic light emitting diode.

In an OLED display, a thin film encapsulation layer can be used as an encapsulation member.

In an organic light emitting diode (OLED) display, a polarizing film is attached to the thin film encapsulation layer so as to improve an image displayed by the organic light emitting element. However, when the polarizing film is detached from the thin film encapsulation layer so as to solve the problem of the bonded state of the polarizing film to the organic light emitting diode (OLED) display, adherence of the polarizing film may cause damages to the surface of the thin film encapsulation layer.

The above information disclosed in this Background section is only for enhancement of understanding of the background of the described technology and therefore it may contain information that does not form the prior art that is already known in this country to a person of ordinary skill in the art.

### SUMMARY

An aspect provides an organic light emitting diode (OLED) display for minimizing generation of damages to the surface of a thin film encapsulation layer when a polarizing film attached to the thin film encapsulation layer is reprocessed while including the thin film encapsulation layer for sealing the organic light emitting element.

An embodiment provides an organic light emitting diode display including: a substrate; an organic light emitting element provided over the substrate; a thin film encapsulation layer configured to seal the organic light emitting element together with the substrate; a phase delay layer provided over the thin film encapsulation layer and contacting the thin film encapsulation layer; and a polarizing film attached to the phase delay layer and having an area smaller than that of the phase delay layer.

Each of the phase delay layer, the substrate, and the thin film encapsulation layer comprises a side, and the sides of the phase delay layer, the substrate, and the thin film encapsulation are placed in the same plane.

Each of the phase delay layer, the substrate, and the thin film encapsulation layer comprises a side having an angle with respect to a plane, and the angle of the substrate, the angle of the thin film encapsulation layer, and the angle of the phase delay layer are the same.

The phase delay layer includes an adhesive layer contacting the thin film encapsulation layer, and a phase delay film provided over the thin film encapsulation layer with the adhesive layer therebetween.

Another embodiment provides a method for manufacturing an organic light emitting diode display, the method including: forming a plurality of organic light emitting elements distanced from each other over a mother substrate; forming a thin film encapsulation layer over the mother substrate so as to encapsulate the plurality of organic light emitting elements together with the mother substrate; forming, over the thin film encapsulation layer, a phase delay layer contacting the thin film encapsulation layer and a protection film attached to the phase delay layer; cutting the mother substrate, the thin film encapsulation layer, the phase delay layer, and the protection film at a region between two immediately neighboring organic light emitting elements among the plurality of organic light emitting elements into a plurality of unfinished organic light emitting diode displays; separating the protection film from the phase delay layer of a first one of the plurality of unfinished organic light emitting diode displays; and attaching a polarizing film to the phase delay layer of the first unfinished organic light emitting diode display wherein the polarizing film has an area smaller than that of the phase delay layer of the first unfinished organic light emitting diode display.

The mother substrate, the thin film encapsulation layer, the phase delay layer, and the protection film are cut by using a single cutting process.

The phase delay layer includes an adhesive layer and a phase delay film attached to the adhesive layer, and the forming of a phase delay layer and a protection film is performed by adhering the phase delay layer using the adhesive layer to the thin film encapsulation layer while the protection film is attached to the phase delay film.

According to the embodiments, an organic light emitting diode (OLED) display for minimizing generation of damages to the surface of the thin film encapsulation layer when the polarizing film attached to the thin film encapsulation layer is reprocessed while including the thin film encapsulation layer for sealing the organic light emitting element is provided.

### BRIEF DESCRIPTION OF THE DRAWINGS

FIG. 1 shows a flowchart of a method for manufacturing an organic light emitting diode (OLED) display according to a first embodiment.

FIG. 2 to FIG. 4 provide illustrations for showing a method for manufacturing an organic light emitting diode (OLED) display according to a first embodiment.

FIG. 4 shows a cross-sectional view of an organic light emitting diode (OLED) display according to a second embodiment.

FIG. 5 shows a layout view of a pixel of an organic light emitting diode (OLED) display according to a second embodiment.

FIG. 6 shows a cross-sectional view with respect to a line VI-VI of FIG. 5.

### DETAILED DESCRIPTION

Embodiments of the present invention will be described more fully hereinafter with reference to the accompanying drawings, in which embodiments of the invention are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present invention is not limited to the illustrated sizes and thicknesses.

In the drawings, the thickness of layers, films, panels, regions, etc., may be exaggerated for clarity. In the drawings, for better understanding and ease of description, the thicknesses of some layers and areas may be exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. In addition, “˜on” is either positioned on or below a portion of a target or positioned on the upper side based on a gravity direction, throughout the specification.

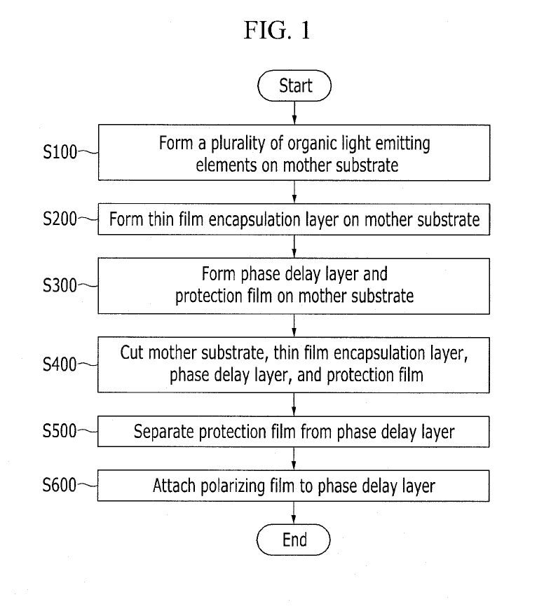

A method for manufacturing an organic light emitting diode (OLED) display according to a first embodiment will now be described with reference to FIG. 1 to FIG. 4.

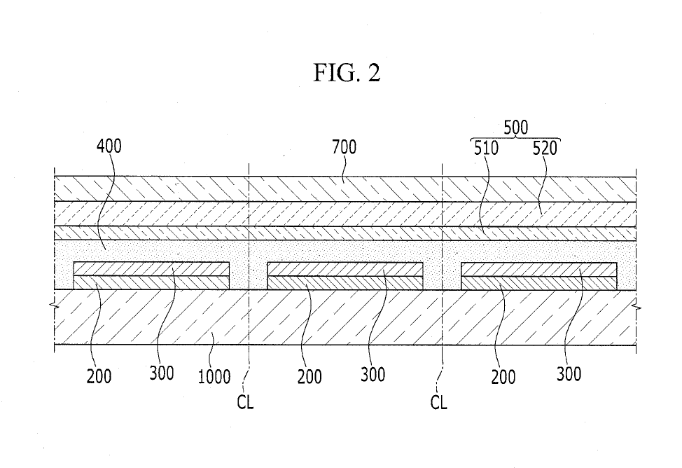

FIG. 1 shows a flowchart of a method for manufacturing an organic light emitting diode (OLED) display according to a first embodiment. FIG. 2 to FIG. 4 show a method for manufacturing an organic light emitting diode (OLED) display according to a first embodiment.

As shown in FIG. 1 and FIG. 2, a plurality of organic light emitting elements 300 are formed on a mother substrate 1000 (S100).

In embodiments, a plurality of wires 200 that are distanced from each other and a plurality of organic light emitting elements 300 that are distanced from each other are formed on the flexible mother substrate 1000. The mother substrate 1000 can include glass, resin, or metal and be made of a light transmissive, light reflective, light absorptive, or semitransparent material. The detailed configuration of the wires 200 and the organic light emitting elements 300 will be described with reference to the organic light emitting diode (OLED) display according to a second embodiment.

A thin film encapsulation layer 400 is formed on the mother substrate 1000 (S200).

In embodiments, the thin film encapsulation layer 400 is formed on the mother substrate 1000 so as to cover the mother substrate 1000 and the organic light emitting elements 300. The thin film encapsulation layer 400 can be formed by alternately stacking at least one organic layer and at least one inorganic layer. In embodiments, the organic layer can be a single layer or a stacked layers which include polyethylene terephthalate (PET), polyimide (PI), or polycarbonate (PC), or it can be a single layer or a stacked layer including engineering plastic including at least one of glass fiber reinforced plastic (FRP), polyethylene terephthalate (PET), and polymethylmethacrylate (PMMA), and the inorganic layer can be a single layer or a stacked layer including at least one of aluminum oxide and silicon oxynitride such as silicon oxide (SiOx), silicon nitride (SiNx), titanium oxide (TiOx), or alumina (Al₂O₃). A highest sublayer of the thin film encapsulation layer 400 that is exposed to the outside can be formed with an inorganic layer to prevent permeation of moisture into the organic light emitting element 300.

A phase delay layer 500 and a protection film 700 are formed on the thin film encapsulation layer 400 (S300).

In embodiments, the phase delay layer 500 includes an adhesive layer 510 and a phase delay film 520 adhered to the adhesive layer 510. The protection film 700 is adhered to the phase delay film 520. The adhesive layer 510 is adhered to the thin film encapsulation layer 400 to form the phase delay layer 500 and the protection film 700 in the thin film encapsulation layer 400. Resultantly, while the protection film 700 is attached to the phase delay layer 500, the phase delay layer 500 contacts the thin film encapsulation layer 400. The phase delay layer 500 may have a phase difference axis of λ/4, and may delay the phase of light passing through the phase delay layer 500 by λ/4 to change the optical axis of the light. The protection film 700 protects the phase delay layer 500 and the thin film encapsulation layer 400 from outer interference. The protection film 700 is exposed to the outside while being attached to the phase delay layer 500 to thus suppress the phase delay layer 500 and the thin film encapsulation layer 400 from being damaged by interference that occurs during a subsequent process.

Accordingly, the phase delay layer 500 and the protection film 700 are formed over the thin film encapsulation layer 400 by using the adhesive layer 510 of the phase delay layer 500 while the protection film 700 is attached to the phase delay film 520 of the phase delay layer 500. Thus, the phase delay layer 500 and the adhesive layer 510 can be formed on the thin film encapsulation layer 400 by a single adhering process. This allows reducing of the time and cost for manufacturing the organic light emitting diode (OLED) display. Thus, the method for manufacturing the organic light emitting diode (OLED) display according to the first embodiment leads the reduction of the time and cost for manufacturing the organic light emitting diode (OLED) display is provided.

In the method for manufacturing the organic light emitting diode (OLED) display according to the first embodiment, the phase delay layer 500 is formed over the thin film encapsulation layer 400 by the adhering process using the adhesive layer 510 included in the phase delay layer 500. In the method for manufacturing the organic light emitting diode (OLED) display according to an alternative embodiment, the phase delay layer is formed on the thin film encapsulation layer 400 by a coating or sputtering process. In this case, after the phase delay layer is formed in the thin film encapsulation layer 400, the protection film 700 is attached to the phase delay layer to form the phase delay layer and the protection film 700 over the thin film encapsulation layer 400.

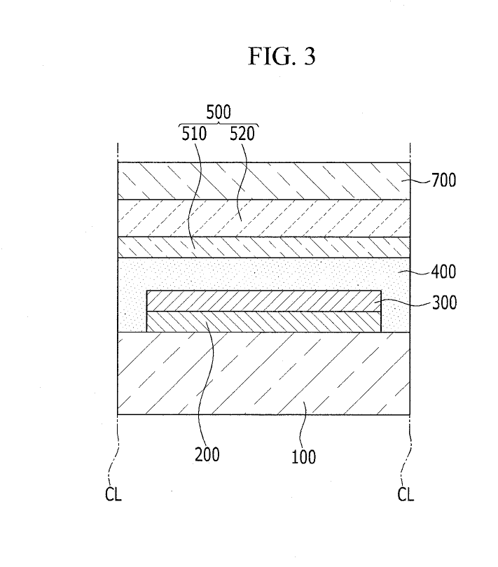

As shown in FIG. 3, the mother substrate 1000, the thin film encapsulation layer 400, the phase delay layer 500, and the protection film 700 are cut (S400).

In embodiments, the mother substrate 1000, the thin film encapsulation layer 400, the phase delay layer 500, and the protection film 700 are cut along a virtual cutting line (CL) provided between two immediately neighboring organic light emitting elements 300 among the plurality of organic light emitting elements 300 by performing a single cutting process using a cutting means such as a laser or diamond cutter. Thus, side surfaces of the substrate 100 that is cut from the mother substrate 1000, the thin film encapsulation layer 400, the phase delay layer 500, and the protection film 700 are provided at the virtual cutting line (CL). In embodiments, the substrate 100, the thin film encapsulation layer 400, the phase delay layer 500, and the protection film 700 are cut by a single cutting process so a cutting angle of a cross-section of the substrate 100 corresponding to the end of the substrate 100, a cutting angle of a cross-section of the thin film encapsulation layer 400 corresponding to the end of the thin film encapsulation layer 400, and a cutting angle of a cross-section of the phase delay layer 500 corresponding to the end of the phase delay layer 500 can be the same.

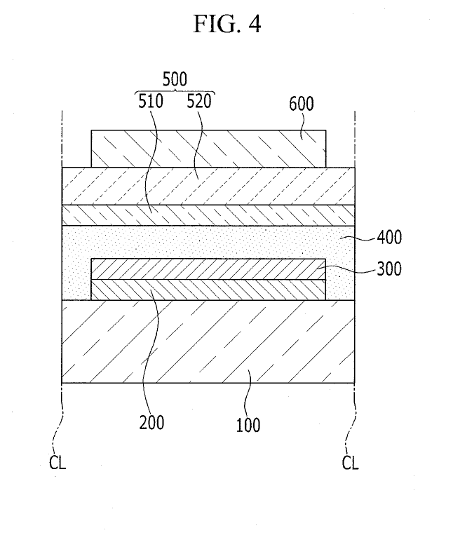

As shown in FIG. 4, the protection film 700 is separated from the phase delay layer 500 (S500).

In embodiments, after various processes, such as, a heat treatment process that is performed after the cutting process is finished are performed, the protection film 700 is separated from the phase delay layer 500.

A polarizing film 600 is attached to the phase delay layer 500 (S600).

In embodiments, a polarizing film 600 that is smaller than the phase delay layer 500 is attached to the phase delay layer 500. The polarizing film 600 has a smaller area than that of the phase delay layer 500 because the phase delay layer 500 and the polarizing film 600 are formed over the thin film encapsulation layer 400 by different processes. The polarizing film 600 can linearly polarize the light passing through the polarizing film 600. The polarizing film 600 controls reflection of outer light incident to the organic light emitting element 300 from the outside together with the phase delay layer 500 to improve the image displayed by the organic light emitting element 300.

According to the above-described process, an organic light emitting diode (OLED) display to be described according to a second embodiment will be manufactured.

During the attaching process of the polarizing film 600 to the phase delay layer 500, the attached state of the polarizing film 600 to the phase delay layer 500 may be bad. When the polarizing film 600 is detached from the phase delay layer 500 so as to solve the bad state of attachment of the polarizing film 600, the surface of the thin film encapsulation layer 400 is protected from damages due to adherence of the polarizing film 600 as the polarizing film 600 does not directly contact the thin film encapsulation layer 400 but is attached to the phase delay layer 500.

Particularly, an inorganic layer having a better waterproofing property than the organic layer is provided in the highest sublayer of the thin film encapsulation layer 400 so as to waterproof the organic light emitting element 300. However, the inorganic layer has brittleness of a ceramic material. Thus, when an optical film such as the polarizing film 600 is attached to the inorganic layer, the inorganic layer may be broken by the adherence of the polarizing film 600 when detaching the polarizing film from the thin film encapsulation layer 400. Thus, in embodiments, the phase delay layer 500 is disposed between the polarizing film 600 and the thin film encapsulation layer 400 in consideration of the brittleness of the inorganic layer provided in the highest layer of the thin film encapsulation layer 400. In other words, the phase delay layer 500 is attached to the thin film encapsulation layer 400 together with the protection film 700 and the polarizing film 600 is then attached to the phase delay layer 500 rather than attaching the polarizing film 600 to the encapsulation layer 400. Thus, when the polarizing film 600 is detached from the phase delay layer 500, generation of damages to the inorganic layer exposed on the surface of the thin film encapsulation layer 400 by the adherence of the polarizing film 600 is avoided.

Also, regarding the method for manufacturing an organic light emitting diode (OLED) display according to the first embodiment, the protection film 700 is attached to the phase delay layer 500 in order to avoid a rupture of the thin film encapsulation layer 400 caused by external interference during the manufacturing process. Thus, when the protection film 700 is separated from the phase delay layer 500 so as to attach the polarizing film 600 thereto, damages to the thin film encapsulation layer 400 due to adherence of the protection film 700 are minimized as the protection film 700 is attached to the phase delay layer 500.

Accordingly, the phase delay layer 500 is formed on the thin film encapsulation layer 400 to prevent the thin film encapsulation layer 400 from being damaged by the adherence of the protection film 700 or the polarizing film 600, and thus, the yield and reliability for the manufacturing process is improved.

An organic light emitting diode (OLED) display according to a second embodiment will now be described with reference to FIG. 4 to FIG. 6.

FIG. 4 shows a cross-sectional view of an organic light emitting diode (OLED) display according to a second embodiment.

As shown in FIG. 4, the organic light emitting diode (OLED) display includes a substrate 100, wires 200, an organic light emitting element 300, a thin film encapsulation layer 400, a phase delay layer 500, and a polarizing film 600.

The substrate 100 includes glass, resin, and metal, and it is made of a light transmissive, light reflective, light absorptive, or semitransparent material. The wires 200 and the organic light emitting element 300 are provided on the substrate 100. The substrate 100 encapsulates the organic light emitting element 300 together with the thin film encapsulation layer 400 with the wires 200 and the organic light emitting element 300 therebetween. The substrate 100 and the thin film encapsulation layer 400 protect the wires 200 and the organic light emitting element 300 from external interference. The substrate 100 can be flexible, and since the thin film encapsulation layer 400 is formed to be a thin film while the substrate 100 is flexible, the organic light emitting diode (OLED) display can be flexible.

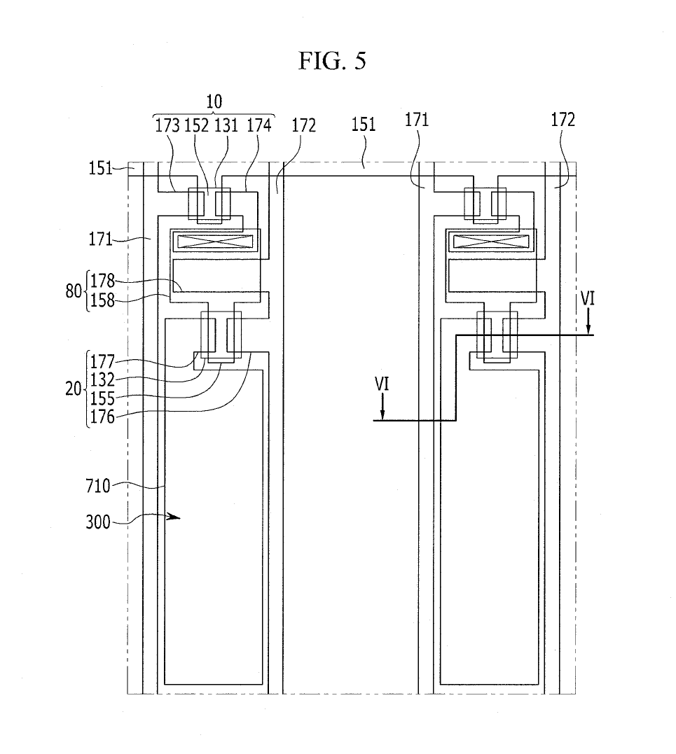

The wires 200 include first and second thin film transistors (10 and 20 in FIG. 5), and transmit a signal to the organic light emitting element 300 to drive the organic light emitting element 300. The organic light emitting element 300 displays an image by emitting light according to the signal provided by the wires 200.

The organic light emitting element 300 is provided on the wires 200.

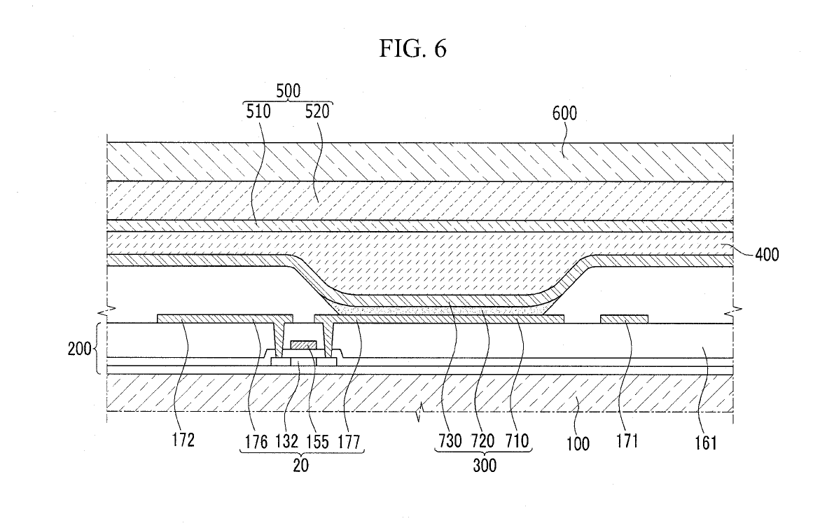

A configuration of the organic light emitting diode (OLED) display according to the second embodiment will now be described with reference FIG. 5 and FIG. 6.

FIG. 5 shows a layout view of a pixel of an organic light emitting diode (OLED) display according to a second embodiment. FIG. 6 shows a cross-sectional view with respect to a line VI-VI of FIG. 5.

While a detailed configuration of the wires 200 and the organic light emitting element 300 is shown in FIG. 5 and FIG. 6, the embodiment is not restricted to the configuration shown in FIG. 5 and FIG. 6. The wires 200 and the organic light emitting element 300 can be formed with various configurations within the range that is easily modifiable by a person skilled in the art. For example, in the drawing, an active matrix (AM) type of organic light emitting diode (OLED) display in the 2Tr-1 Cap structure including two thin film transistors (TFT) and a single capacitor for each pixel is shown for the organic light emitting diode (OLED) display, and the present invention is not limited thereto. Therefore, the organic light emitting diode (OLED) display does not have limits of the number of the thin film transistors, the number of the capacitors, and the number of the wires. A pixel represents the minimum unit for displaying the image, and the organic light emitting diode (OLED) display displays the image by using a plurality of pixels.

As shown in FIG. 5 and FIG. 6, the organic light emitting diode (OLED) display according to the second embodiment includes a switching thin film transistor 10, a drive thin film transistor 20, a capacitor 80, and an organic light emitting element 300 for each pixel. Here, the switching thin film transistor 10, the drive thin film transistor 20, and the capacitor 80 configure the wires 200. The wires 200 further include a gate line 151 disposed in one direction of the substrate 100, a data line 171 crossing the gate line 151 in an insulated manner, and a common power line 172. In embodiments, one pixel is defined by a boundary of the gate line 151, the data line 171, and the common power line 172, and it is not limited thereto.

The organic light emitting element 300 includes a first electrode 710, an organic emission layer 720 formed on the first electrode 710, and a second electrode 730 formed on the organic emission layer 720. The first electrode 710, the organic emission layer 720, and the second electrode 730 form the organic light emitting element 300. Here, the first electrode 710 becomes an anode, which is a hole injection electrode, and the second electrode 730 becomes a cathode, which is an electron injection electrode. However, the embodiment is not restricted thereto, and the first electrode 710 can become a cathode and the second electrode 730 can become an anode depending on the method for driving the organic light emitting diode (OLED) display. Holes and electrons are injected into the organic emission layer 720 from the first electrode 710 and the second electrode 730, and the organic emission layer 720 emits light when exitons generated by combination of the holes and the electrons that are injected into the organic emission layer 720 enter the ground state from the excitation state. Also, at least one of the first electrode 710 and the second electrode 730 can be formed in the light transmissive structure so the organic light emitting element 300 emits light in the direction of the thin film encapsulation layer 400 to display the image in the direction of the thin film encapsulation layer 400.

The capacitor 80 includes a pair of capacitor plates 158 and 178 disposed with an interlayer insulating layer 161 therebetween. In embodiments, the interlayer insulating layer 161 is a dielectric material, and capacitance of the capacitor 80 is determined by the charges stored in the capacitor 80 and the voltage between the capacitor plates 158 and 178.

The switching thin film transistor 10 includes a switching semiconductor layer 131, a switching gate electrode 152, a switching source electrode 173, and a switching drain electrode 174. The drive thin film transistor 20 includes a drive semiconductor layer 132, a drive gate electrode 155, a drive source electrode 176, and a drive drain electrode 177.

The switching thin film transistor 10 is used as a switch for selecting a pixel to emit light. The switching gate electrode 152 is connected to the gate line 151. The switching source electrode 173 is connected to the data line 171. The switching drain electrode 174 is distanced from the switching source electrode 173 and is connected to one (158) of the capacitor plates.

The drive thin film transistor 20 applies drive power for emitting the organic emission layer 720 of the organic light emitting element 300 in the selected pixel to the second electrode 730. The drive gate electrode 155 is connected to the capacitor plate 158 connected to the switching drain electrode 174. The drive source electrode 176 and the other capacitor plate 178 are connected to the common power line 172. The drive drain electrode 177 is provided in the same layer as the first electrode 710 and is connected to the first electrode 710.

The drive drain electrode 177 of the organic light emitting diode (OLED) display according to the second embodiment is provided in the same layer as the first electrode 710, and the drive drain electrode of the organic light emitting diode (OLED) display according to another embodiment is provided in the different layer to that of the first electrode and can contact the first electrode through an opening that is formed in the insulating layer.

According to the above-described configuration, the switching thin film transistor 10 is operable by the gate voltage applied to the gate line 151 to transmit the data voltage applied to the data line 171 to the drive thin film transistor 20. A voltage that corresponds to a difference between a common voltage applied to the drive thin film transistor 20 from the common power line 172 and the data voltage transmitted by the switching thin film transistor 10 is stored in the capacitor 80, and a current that corresponds to the voltage stored in the capacitor 80 flows to the organic light emitting element 300 through the drive thin film transistor 20 so that the organic light emitting element 300 emits light.

Referring to FIG. 4 and FIG. 6, a thin film encapsulation layer 400 is provided on the organic light emitting element 300.

The thin film encapsulation layer 400 faces the substrate 100 with the organic light emitting element 300 therebetween, and covers the organic light emitting element 300 to seal the organic light emitting element 300.

The thin film encapsulation layer 400 can be formed by alternately stacking at least one organic layer and at least one inorganic layer. Here, the organic layer can be a single layer or stacked layers which include a resin such as polyethylene terephthalate (PET), polyimide (PI), or polycarbonate (PC), or it can be a single layer or stacked layers including engineering plastic including at least one of glass fiber reinforced plastic (FRP), polyethylene terephthalate (PET), and polymethylmethacrylate (PMMA), and the inorganic layer can be a single layer or stacked layers including at least one of aluminum oxide and silicon oxynitride such as silicon oxide (SiOx), silicon nitride (SiNx), titanium oxide (TiOx), or alumina (Al₂O₃). In addition, the highest sublayer of the thin film encapsulation layer 400 that is exposed to the outside can be formed with an inorganic layer for preventing permeation of moisture into the organic light emitting element 300.

A phase delay layer 500 is provided in the thin film encapsulation layer 400.

The phase delay layer 500 contacts the thin film encapsulation layer 400, and includes an adhesive layer 510 and a phase delay film 520 adhered to the adhesive layer 510. The adhesive layer 510 supports the phase delay layer 500 to be adhered between the thin film encapsulation layer 400, and the phase delay film 520 delays the phase of light passing through the phase delay layer 500 by λ/4 to change the optical axis of the light.

Cut sides of the substrate 100, the thin film encapsulation layer 400, and the phase delay layer 500 are placed in the same plane illustrated as the same cutting line (CL), and the cutting angle of the cross-section of the substrate 100 corresponding to the end of the substrate 100, the cutting angle of the cross-section of the thin film encapsulation layer 400 corresponding to the end of the thin film encapsulation layer 400, and the cutting angle of the cross-section of the phase delay layer 500 corresponding to the end of the phase delay layer 500 can be the same.

In the organic light emitting diode (OLED) display according to the second embodiment, the phase delay layer 500 includes the adhesive layer 510 and the phase delay film 520. In the organic light emitting diode (OLED) display according to another embodiment, the phase delay layer can be formed on the thin film encapsulation layer 400 by a coating or sputtering process to thus form a single layer.

A polarizing film 600 is provided in the phase delay layer 500.

The polarizing film 600 is smaller than the phase delay layer 500, and it is attached to the phase delay layer 500. The polarizing film 600 linearly polarizes the light passing through the polarizing film 600, and suppresses reflection of the external light irradiated to the organic light emitting element 300 from the outside together with the phase delay layer 500 to improve the image displayed by the organic light emitting element 300.

Accordingly, organic light emitting diode (OLED) display according to the second embodiment is manufactured by the method for manufacturing the organic light emitting diode (OLED) display according to the first embodiment, so generation of damage to the thin film encapsulation layer 400 by adherence of the protection film 700 or the polarizing film 600 during the manufacturing process is prevented, thereby reducing the production time and cost.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display comprising:
a substrate;
an organic light emitting element provided over the substrate;
a thin film encapsulation layer configured to seal the organic light emitting element together with the substrate;
a phase delay layer provided over the thin film encapsulation layer and contacting the thin film encapsulation layer; and
a polarizing film attached to the phase delay layer and having an area smaller than that of the phase delay layer.

2. The organic light emitting diode display of claim 1, wherein each of the phase delay layer, the substrate, and the thin film encapsulation layer comprises a side, and
wherein the sides of the phase delay layer, the substrate, and the thin film encapsulation are placed in the same plane.

3. The organic light emitting diode display of claim 1, wherein each of the phase delay layer, the substrate, and the thin film encapsulation layer comprises a side having an angle with respect to a plane, and
wherein the angle of the substrate, the angle of the thin film encapsulation layer, and the angle of the phase delay layer are the same.

4. The organic light emitting diode display of claim 1, wherein the phase delay layer comprises:
an adhesive layer contacting the thin film encapsulation layer; and
a phase delay film provided over the thin film encapsulation layer with the adhesive layer therebetween.

5. A method for manufacturing an organic light emitting diode display, the method comprising:
forming a plurality of organic light emitting elements distanced from each other over a mother substrate;
forming a thin film encapsulation layer over the mother substrate so as to encapsulate the plurality of organic light emitting elements together with the mother substrate;
forming, over the thin film encapsulation layer, a phase delay layer contacting the thin film encapsulation layer and a protection film attached to the phase delay layer;
cutting the mother substrate, the thin film encapsulation layer, the phase delay layer, and the protection film at a region between two immediately neighboring organic light emitting elements among the plurality of organic light emitting elements into a plurality of unfinished organic light emitting diode displays;
separating the protection film from the phase delay layer of a first one of the plurality of unfinished organic light emitting diode displays; and
attaching a polarizing film to the phase delay layer of the first unfinished organic light emitting diode display wherein the polarizing film has an area smaller than that of the phase delay layer of the first unfinished organic light emitting diode display.

6. The method of claim 5, wherein the mother substrate, the thin film encapsulation layer, the phase delay layer, and the protection film are cut by using a single cutting process.

7. The method of claim 5, wherein the phase delay layer comprises an adhesive layer and a phase delay film attached to the adhesive layer, and
wherein the forming of a phase delay layer and a protection film is performed by adhering the phase delay layer using the adhesive layer to the thin film encapsulation layer while the protection film is attached to the phase delay film.
